(19) United States
(12) Patent Application Publication
(10) Pub. No.: US 2026/0156898 A1
(43) Pub. Date: Jun. 4, 2026

(54) METHOD OF MANUFACTURING SEMICONDUCTOR DEVICE AND SEMICONDUCTOR DEVICE

(71) Applicant: HON HAI PRECISION INDUSTRY CO., LTD., New Taipei City (TW)

(72) Inventors: Jheng-Sheng YOU, Hsinchu City (TW); Jhe-Hao CHANG, Hsinchu City (TW); Wen-Yuan HSIEH, Hsinchu City (TW)

(21) Appl. No.: 19/050,078

(22) Filed: Feb. 10, 2025

(30) Foreign Application Priority Data
Nov. 29, 2024 (TW) 113146432

(51) Int. Cl. H10D 64/27; H01L 23/00; H01L 23/528; H10D 64/23

(52) U.S. Cl. CPC H10D 64/512; H10D 64/258; H10D 64/518; H10W 20/435; H10W 72/921; H10W 72/942; H10W 72/952

(57) ABSTRACT

A semiconductor device is provided, including: a substrate, a channel layer, a barrier layer, a gate structure, a dielectric layer, a gate plug and a gate connection pad. The channel layer is disposed on the substrate; the barrier layer is disposed on the channel layer; the gate structure is disposed on part of the barrier layer; the dielectric layer is disposed on the barrier layer and the gate structure; the gate plug is disposed on the dielectric layer and in contact with the gate structure; and the gate connection pad is disposed on the gate plug.

### CROSS-REFERENCE TO RELATED APPLICATION

This application claims priority to Taiwan Application Serial Number 113146432, filed on Nov. 29, 2024, which is herein incorporated by reference in its entirety.

### BACKGROUND

### Field of Invention

The present invention relates to a semiconductor device and method of manufacturing the same.

### Description of Related Art

Power semiconductor devices continue to develop and are widely used in wireless communications, electronic products, electric vehicles, etc. However, components that can withstand high power need to have high breakdown voltage, and better components also need to have high electron mobility, good thermal stability, etc. Therefore, a new semiconductor device and method of forming the same are needed to continue the development of related fields.

### SUMMARY

The present disclosure provides a method of manufacturing semiconductor device, comprising: providing a substrate, a channel layer disposed on the substrate, and a barrier layer disposed on the channel layer; forming a gate structure on a portion of the barrier layer; forming a dielectric layer on the barrier layer and the gate structure; forming a gate plug in the dielectric layer and contacting the gate structure; and forming a gate pad on the gate plug.

The present disclosure also provides a semiconductor device, comprising a substrate, a channel layer, a barrier layer, a gate structure, a dielectric layer, a gate plug, and a gate pad. The channel layer disposed on the substrate. The barrier layer disposed on the channel layer. The gate structure disposed on a portion of the barrier layer. The dielectric layer disposed on the barrier layer and the gate structure. The gate plug disposed in the dielectric layer and contacting the gate structure. The gate pad disposed on the gate plug.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion. The disclosure can be more fully understood by reading the following detailed description of the embodiment, with reference made to the accompanying drawings as follows:

FIG. 1 is a perspective view of a semiconductor device according to some embodiments of the present disclosure.

FIG. 2 is a flow chart of a method of manufacturing the semiconductor device according to an embodiment of the present disclosure.

FIGS. 3 to 5 are cross-sectional views of manufacturing the semiconductor device at different manufacturing stages according to an embodiment of the present disclosure.

FIG. 6 is a cross-sectional view of the semiconductor device according to another embodiment of the present disclosure.

### DETAILED DESCRIPTION

Gallium nitride (GaN) semiconductor devices are increasingly used because of their ability to carry large currents and support high voltages. In order to reduce gate resistance, the gate metal is used for the existing gallium nitride semiconductor devices for metal connections in the active region. However, in the manufacturing process, the opening must be formed on the dielectric layer first, and then the gate metal located in and on the opening must be deposited, which makes the manufacturing process cumbersome and complicated. Furthermore, the dielectric layer is limited because of unplanarized structure and the gate metal etching, so only 2˜4KA copper-aluminum (AlCu) can be used as the gate metal material.

Therefore, some embodiments of the present disclosure provide a semiconductor device and a method of manufacturing the same, which directly contact the gate (including the gate electrode layer) and the gate bus line extending to the active region through the gate plug, for example, using ME1 6˜18KA AlCu as the connecting wire can significantly reduce the gate resistance by about 65%. In addition, the gate metal process can be reduced and the photomask step can be saved by directly contacting the gate plug with the gate structure (excluding the gate electrode layer).

A number of examples are provided herein to elaborate the method of manufacturing semiconductor device and semiconductor device of the instant disclosure. However, the examples are for demonstration purpose alone, and the instant disclosure is not limited thereto.

Although a series of operations or steps are used below to describe the method disclosed herein, an order of these operations or steps should not be construed as a limitation to the present invention. For example, some operations or steps may be performed in a different order and/or other steps may be performed at the same time. In addition, all shown operations, steps and/or features are not required to be executed to implement an embodiment of the present invention. In addition, each operation or step described herein may include a plurality of sub-steps or actions.

For the sake of clarity, features and elements that are well known in the art and are not necessary for an understanding of the principles described have been omitted.

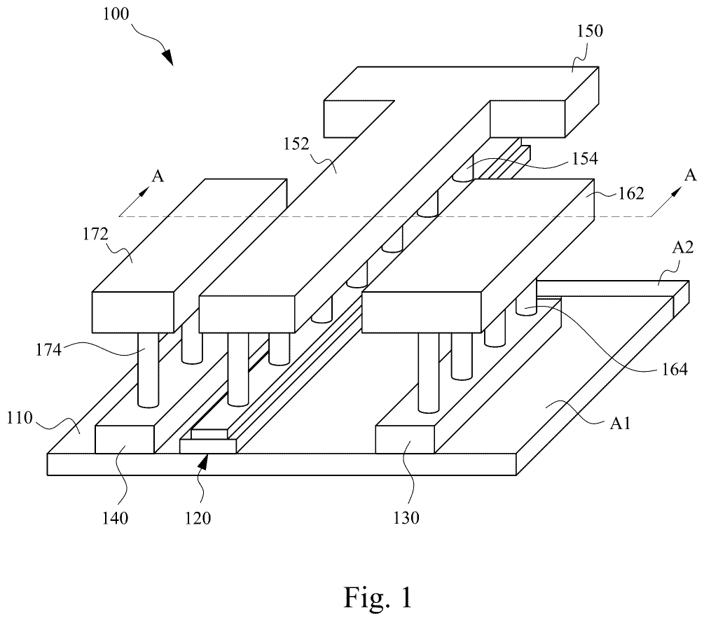

Please refers to FIG. 1, FIG. 1 is a perspective view of a semiconductor device according to some embodiments of the present disclosure. The semiconductor device 100 includes a semiconductor substrate 110. An active region A1 and isolation regions A2 are defined in the semiconductor substrate 110, in which the isolation regions A2 are disposed at opposite sides of the active region A1 (only one side is illustrated in the drawing). The channel layer of the active region A1 is not damaged, and the channel layer of the isolation region A2 is damaged by such as an ion bombard process. The semiconductor device 100 includes a gate structure 120, a drain electrode 130, and a source electrode 140 disposed on the active region A1 of the semiconductor substrate 110. The gate structure 120, the drain electrode 130, and the source electrode 140 are substantially parallel arranged, and the drain electrode 130 and the source electrode 140 are disposed at opposite sides of the gate structure 120.

The semiconductor device 100 includes a gate bus 150 disposed on the isolation region A2. The semiconductor device 100 includes a gate pad 152 connected to the gate bus 150 and extended into the active region A1. The extension direction of the gate bus 150 is perpendicular to the extension direction of the gate pad 152. The gate pad 152 overlaps the gate structure 120 in a vertical projection. The semiconductor device 100 further includes a plurality of gate plugs 154. The gate plugs 154 are disposed on the active region A1 and electrically connect the gate pad 152 to the gate structure 120.

The semiconductor device 100 further includes a drain bus (not shown) and a source bus (not shown) disposed at the isolation region (not shown) at another side of the active region A1 (which is the active region A2). The semiconductor device 100 further includes a drain pad 162 connected to the drain bus and extended into the active region A1 and a source pad 172 connected to the source bus and extended into the active region A1. The extension direction of the drain pad 162 and source pad 172 is parallel to the extension direction of the gate pad 152. The semiconductor device 100 further includes a plurality of drain plugs 164 and a plurality of source plugs 174. The drain plugs 164 and the source plugs 174 are disposed on the active region A1. The drain plugs 164 electrically connect the drain pad 162 to the drain electrode 130, and the source plugs 174 electrically connect the source pad 172 to the source electrode 140.

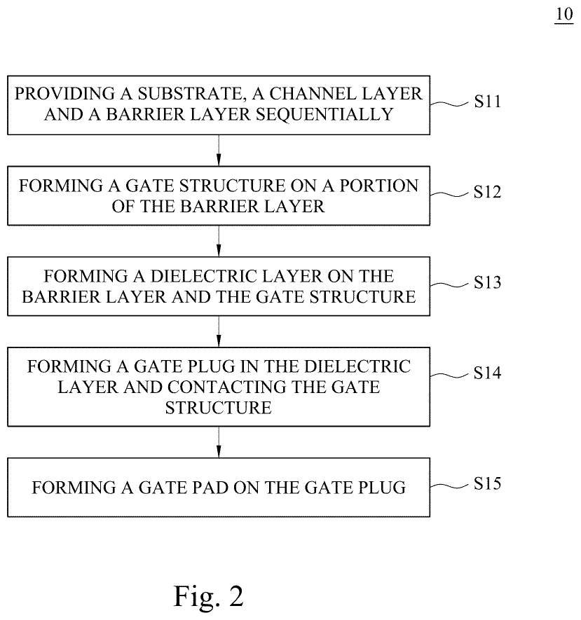

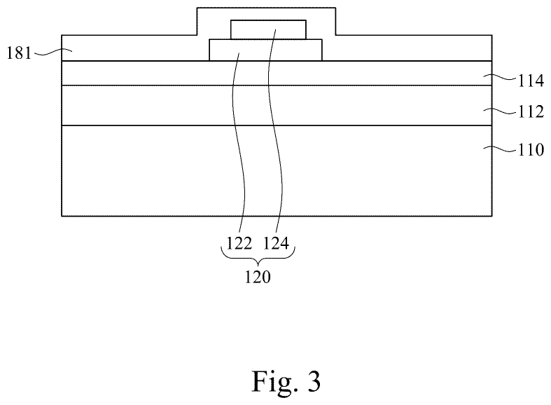

Please refer to FIG. 2 with FIGS. 3 to 5, FIG. 2 is a flow chart of a method of manufacturing the semiconductor device according to an embodiment of the present disclosure, and FIGS. 3 to 5 are cross-sectional views of manufacturing the semiconductor device at different manufacturing stages according to an embodiment of the present disclosure. As shown in FIG. 2, the method 10 includes step S11 to step S15.

In the step S11, a substrate 110, a channel layer 112, and a barrier layer 114 are sequentially provided. As shown in FIG. 3, the cross-sectional position can refer to line A-A in FIG. 1. The substrate 110 is silicon substrate. The method of manufacturing a semiconductor device includes forming a channel layer 112 on the semiconductor substrate 110 and forming a barrier layer 114 on the channel layer 112. The semiconductor substrate 110 may be a silicon substrate or a silicon carbide substrate, etc., and can further include semiconductor elements, compounds and/or alloys.

The channel layer 112 can provide a channel between source and drain. The barrier layer 114 is benefit to form a two-dimensional electron gas (2DEG) carrier path within the channel layer 112, in which the 2DEG carrier path has high concentration, high electron mobility, and lower resistance. In some embodiments, the material of the channel layer 112 includes epitaxial GaN, AlN, AlGaN, etc. In some embodiments, the material of the barrier layer 114 includes GaN, AlN, AlGaN, etc.

Then in the step S12, the gate structure 120 is formed on the barrier layer 114 to control the carrier passing or not of the channel layer 112. In some examples, the gate structure 120 includes a patterned doping layer 122 and a gate metal layer 124 on the doping layer 122. Such as in some examples, the doping layer 122 includes GaN doped with P-type dopants. The material of the gate metal layer 124 can include suitable metal materials, such as TIN, etc.

Then in the step S13, a dielectric layer 180 is formed on the barrier layer 114 and the gate structure 120. A first dielectric layer 181 is conformally and continuously formed on the barrier layer 114 and the gate structure 120. The first dielectric layer 181 is directly in contact with the barrier layer 114 and the gate structure 120. In some embodiments, the first dielectric layer 181 covers the barrier layer 114 and continuously covers a top surface and side surfaces of the gate structure 120.

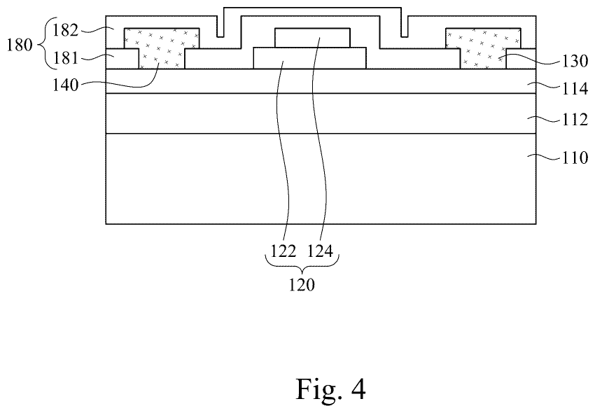

Then, as shown in FIG. 4, a drain electrode 130 and a source electrode 140 are formed at opposite sides of the gate structure 120 and in contact with the barrier layer 114, respectively. The material of the drain electrode 130 and the source electrode 140 is ohmic contact metal which can be selected corresponding to the barrier layer 114. In some examples, the ohmic contact metal of the drain electrode 130 and the source electrode 140 includes Ti, Al, AlSi, AlCu, AlN, Ni, Pt, Au, etc. The drain electrode 130 and the source electrode 140 penetrate the first dielectric layer 181 and contact the barrier layer 114.

Then, a dielectric layer 180 is formed on the barrier layer 114, the drain electrode 130, the source electrode 140, and the gate structure 120. In some examples, second dielectric layer 182 is formed covering the drain electrode 130, the source electrode 140, and the first dielectric layer 181. In some examples, the material of the first dielectric layer 181 and the second dielectric layer 182 includes SiO₂, Si₃N₄, SiON, or combinations thereof. After the second dielectric layer 182 is formed, a patterned photoresist can be formed on a portion of the semiconductor substrate 110 as the active region A1 (see FIG. 2), and portions of the semiconductor substrate 110 as the isolation regions A2 (see FIG. 2) are exposed. A plasma bombard process is then performed to destroy the channel layer 112 in the isolation regions A2. Then the patterned photoresist is removed to define the active region A1 and the isolation regions A2.

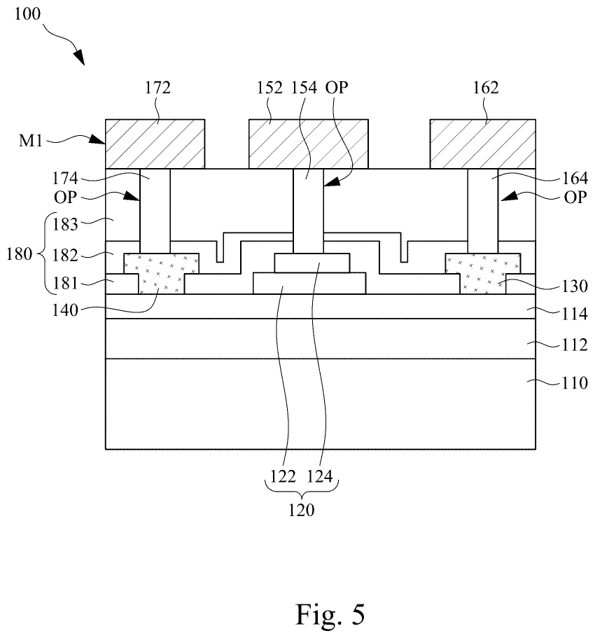

Then, as shown in FIG. 5, a third dielectric layer 183 is deposited on the second dielectric layer 182, and a planarization process is performed such that the third dielectric layer 183 is able to provide a planar top surface. The first dielectric layer 181, the second dielectric layer 182, and the third dielectric layer 183 together can be referred as a dielectric layer 180.

Then in the step S14, the gate plug 154 is formed in the dielectric layer 180 and contacting the gate structure 120, furthermore, the drain plug 164 and the source plug 174 are formed in the dielectric layer 180, and the drain plug 164 and the source plug 174 are in contact with the drain electrode 130 and the source electrode 140, respectively. In some examples, the dielectric layer 180 is etched to define a plurality of openings OP therein. A metal material such as tungsten is deposited to fill the openings OP thereby forming the plurality of gate plugs 154 that are connected to the gate structure 120, the plurality of drain plugs 164 that are connected to the drain electrode 130, and the plurality of source plugs 174 that are connected to the source electrode 140.

Then in the step S15, the gate pad 152 is formed on the gate plug 154, furthermore, the drain pad 162 and the source pad 172 are formed on the drain plug 164 and the source plug 174, respectively. In some examples, after the gate plugs 154, the drain plugs 164, and the source plugs 174 are formed on the active region A1, a first metal layer M1 is deposited on the dielectric layer 180 and is patterned to obtain the gate bus 150 (see FIG. 2) and the gate pad 152, the drain bus (not shown) and the drain pad 162, the source bus (not shown) and the source pad 172. In some examples, the material of the first metal layer M1 is metal material having low resistance such as AlCu, Al, AlSi, Cu, or other low resistance metals. In some examples, the thickness of the metal layer M1 is greater than that of the gate metal layer 124 to achieve a significant reduction in gate resistance, thereby reducing switching losses and increasing the switching frequency when the gate control element is switched. For example, the thickness of the gate metal layer 124 is ranging from 500 Å to 1500 Å, and the thickness of metal layer M1 is ranging from 4000 Å to 40000 Å.

In some examples, the gate pad 152, the drain pad 162 and source pad 172 are arranged in parallel along the same direction in the same active region A1 of substrate 110. Specifically, the semiconductor device 100 includes the gate structure 120, the drain electrode 130 and the source electrode 140 arranged in parallel on the active region A1, and the corresponding gate pad 152, the drain pad 162 and the source pad 172 arranged in parallel in the vertical projection direction. The gate plug 154 of the semiconductor device 100 is disposed on the active region A1 and connects the gate pad 152 to the gate structure 120. The drain plug 164 of the semiconductor device 100 is disposed on the active region A1 and connects the drain pad 162 to the drain electrode 130. The source plug 174 of the semiconductor device 100 is disposed on the active region A1 and connects the source pad 172 to the source electrode 140.

In some examples, the gate plugs 154, the drain plugs 164, and the source plugs 174 are disposed only on the active region A1 and are not disposed on the isolation region A2.

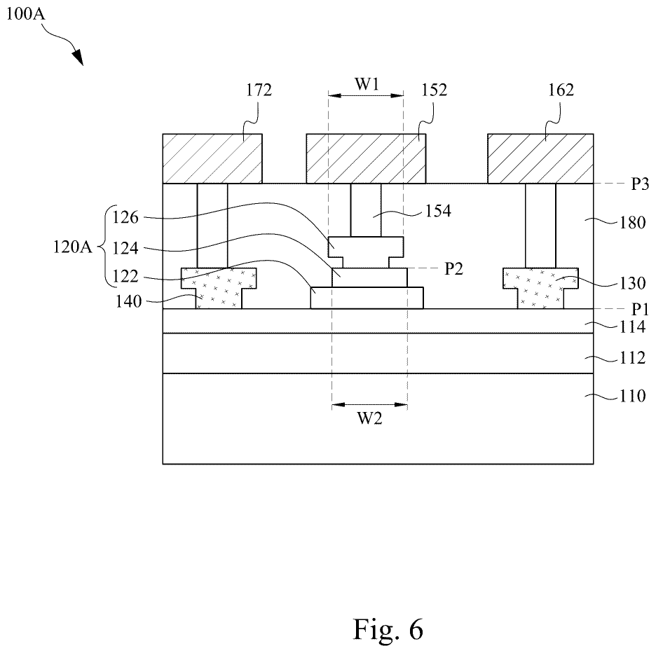

Please refer to FIG. 6, which is a cross-sectional view of the semiconductor device according to another embodiment of the present disclosure, in which the cross-section can refer to line A-A of FIG. 2. In some examples, as shown in the semiconductor device 100A, the gate structure 120A can further include a gate electrode layer 126 disposed on the gate metal layer 124 and covered by the dielectric layer 180, to further reduce the resistance of the gate structure 120A. The gate electrode layer 126 can be single layer or multiple layers of conductive materials. In some examples, the material of the gate electrode layer 126 includes TiN, Ti, AlCu, or combinations thereof.

In some examples, the top of the gate electrode layer 126 is wider than the bottom of the gate electrode layer 126 such as a width W1 of the top surface of the gate electrode layer 126 is greater than a width W2 of the gate metal layer 124 thereby increasing a contact area between the gate plugs 154 and the gate structure 120A, to further reduce the contact resistance between the gate plugs 154 and the gate structure 120A.

As shown in the examples, the gate electrode layer 126, the drain electrode 130 and the source electrode 140 are located in different layers. Specifically, a lower surface of the gate electrode layer 126 is higher than a lower surface of the drain electrode 130 and a lower surface of the source electrode 140. A lower surface of the gate pad 152, a lower surface of the drain pad 162 and a lower surface of the source pad 172 are higher than an upper surface of the gate electrode layer 126. In some examples, a plane P2 where the gate electrode layer 126 is located is higher than a plane P1 where the drain electrode 130 and the source electrode 140 are located, and a plane P3 where the gate pad 152, the drain pad 162 and the source pad 172 are located is higher than a plane P2 where the gate electrode layer 126 is located.

In summary, in some examples of the semiconductor device of the present disclosure, the gate structure and the gate pad are connected by the gate plug in the active region. Since the gate pad extends from the gate bus line, the same low-resistance metal material can be used as the connecting wire and greatly reducing the gate resistance.

While the disclosure has been described by way of example(s) and in terms of the preferred embodiment(s), it is to be understood that the disclosure is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A method of manufacturing semiconductor device, comprising:
providing a substrate, a channel layer disposed on the substrate, and a barrier layer disposed on the channel layer;
forming a gate structure on a portion of the barrier layer;
forming a dielectric layer on the barrier layer and the gate structure;
forming a gate plug in the dielectric layer and contacting the gate structure; and
forming a gate pad on the gate plug.

2. The method of claim 1, wherein the gate structure comprises:
a doping layer, disposed on the gate structure; and
a gate metal layer, disposed on the doping layer.

3. The method of claim 1, further comprising:
forming a drain electrode and a source electrode respectively contacting the barrier layer, and respectively disposed at two sides of the gate structure;
forming the dielectric layer on the barrier layer, the drain electrode, the source electrode, and the gate structure;
forming a drain plug and a source plug in the dielectric layer, and the drain plug and the source plug respectively contacting the drain electrode, the source electrode; and
forming a drain pad and a source pad on the drain plug and the source plug, respectively.

4. The method of claim 3, wherein before the forming the dielectric layer, the method further comprises: forming a gate electrode layer on the gate structure, wherein, a lower surface of the gate electrode layer is higher than a lower surface of the drain electrode and a lower surface of the source electrode, and a lower surface of the gate pad, a lower surface of the source pad, and a lower surface of the drain pad are higher than a lower surface of the gate electrode layer.

5. A semiconductor device, comprising:
a substrate;
a channel layer disposed on the substrate;
a barrier layer disposed on the channel layer;
a gate structure disposed on a portion of the barrier layer;
a dielectric layer disposed on the barrier layer and the gate structure;
a gate plug disposed in the dielectric layer and contacting the gate structure; and
a gate pad disposed on the gate plug.

6. The semiconductor device of claim 5, wherein the gate structure comprises:
a doping layer disposed on the gate structure; and
a gate metal layer disposed on the doping layer.

7. The semiconductor device of claim 6, further comprising:
a drain electrode and a source electrode respectively contacting the barrier layer, and the drain electrode and the source electrode respectively disposed at two sides of the gate structure;
the dielectric layer covering the barrier layer, the drain electrode, the source electrode, and the gate structure;
a drain plug and a source plug disposed in the dielectric layer, and the drain plug and the source plug respectively contacting the drain electrode and the source electrode; and
a drain pad and a source pad respectively disposed on the drain plug and the source plug.

8. The semiconductor device of claim 7, wherein in a top view, the gate pad, the drain pad, and the source pad are arranged in parallel along a same direction in a same active region of the substrate.

9. The semiconductor device of claim 7, wherein a thickness of the gate pad, the drain pad, and the source pad is greater than the gate metal layer.

10. The semiconductor device of claim 7, further comprising:
a gate electrode layer disposed on the gate structure, and covered by the dielectric layer; wherein, the gate electrode layer, the drain electrode, and the source electrode are located at different layers.

11. The semiconductor device of claim 10, wherein the drain pad is at the same level as the gate pad, and the drain pad overlaps the drain electrode in a vertical projection.

12. The semiconductor device of claim 11, wherein a width of a top surface of the gate electrode layer is greater than a width of the gate metal layer.

13. The semiconductor device of claim 12, wherein a plane on where the gate electrode layer is located is higher than a plane on where the drain electrode and the source electrode are located.

14. The semiconductor device of claim 12, wherein a plane on where the gate pad is located is higher than a plane on where the gate electrode layer is located.

15. The semiconductor device of claim 5, wherein a material of the gate pad comprises AlCu.
